(19) United States
(12) Patent Application Publication
(10) Pub. No.: US 2024/0194751 A1
(43) Pub. Date: Jun. 13, 2024

(54) TRANSISTOR DEVICES INCLUDING SELF-ALIGNED OHMIC CONTACTS AND CONTACT REGIONS AND RELATED FABRICATION METHODS

(71) Applicant: Wolfspeed, Inc., Durham, NC (US)

(72) Inventors: Kyle Bothe, Cary, NC (US); Chris Hardiman, Morrisville, NC (US); Chloe Hawes, Asheville, NC (US); Daniel Namishia, Wake Forest, NC (US); Evan Jones, Durham, NC (US)

(21) Appl. No.: 18/063,787

(22) Filed: Dec. 9, 2022

(51) Int. Cl. H01L 29/417; H01L 23/66; H01L 29/40

(52) U.S. Cl. CPC H01L 29/41783; H01L 23/66; H01L 29/401; H01L 29/7786

(57) ABSTRACT

A transistor device includes a semiconductor structure having an implanted region adjacent a surface thereof; and a source/drain contact including an ohmic contact portion on the implanted region of the semiconductor structure. The implanted region laterally extends beyond the ohmic contact portion by less than about 0.8 microns, e.g., by less than about 0.2 microns or such that a boundary of the implanted region is substantially aligned with an edge of the ohmic contact portion. Related fabrication methods are also discussed.

### FIELD

The inventive concepts described herein relate to semiconductor devices, and more particularly, to transistor devices and related fabrication methods.

### BACKGROUND

Power semiconductor devices are widely used to carry large currents, support high voltages and/or operate at high frequencies such as radio frequencies. A wide variety of power semiconductor devices are known in the art including, for example, power switching devices and power amplifiers. Many power semiconductor devices are implemented using various types of field effect transistor (FET) devices including MOSFETs (metal-oxide semiconductor field-effect transistors), DMOS (double-diffused metal-oxide semiconductor) transistors, HEMTs (high electron mobility transistors), MESFETs (metal-semiconductor field-effect transistors), LDMOS (laterally-diffused metal-oxide semiconductor) transistors, etc.

Modern power semiconductor devices are generally fabricated from wide bandgap semiconductor materials (i.e., having a band-gap greater than 1.40 eV). For example, power HEMTs may be fabricated from gallium nitride (GaN) or other Group III nitride based material systems that are formed on a silicon carbide (SiC) substrate. As used herein, the term “Group III nitride” refers to those semiconducting compounds formed between nitrogen and the elements in Group III of the periodic table, usually aluminum (Al), gallium (Ga), and/or indium (In). These compounds have empirical formulas in which one mole of nitrogen is combined with a total of one mole of the Group III elements. For high power, high temperature, and/or high frequency applications, devices formed in wide bandgap semiconductor materials such as silicon carbide (2.996 eV bandgap for alpha silicon carbide at room temperature) and the Group III nitrides (e.g., 3.36 eV bandgap for gallium nitride at room temperature) may provide higher electric field breakdown strengths and higher electron saturation velocities as compared to gallium arsenide (GaAs) and silicon (Si) based devices.

In order to increase the output power and current handling capabilities, power semiconductor devices may be implemented in a “unit cell” configuration in which a large number of individual unit cell transistor structures of the active region are electrically connected (e.g., in parallel) to function as a single power semiconductor device. In high power applications, such a power semiconductor device may include thousands or tens of thousands of unit cells implemented in a single chip or “die.” A die or chip may include a small block of semiconducting material or other substrate in which electronic circuit elements are fabricated.

Field effect transistors such as HEMTs and MOSFETs may be classified into depletion mode and enhancement mode types, corresponding to whether the transistor is in an ON-state or an OFF-state at a gate-source voltage of zero. In enhancement mode devices, the devices are OFF at zero gate-source voltage, whereas in depletion mode devices, the device is ON at zero gate-source voltage. Conventional high performance Group III nitride-based HEMTs may typically be implemented as depletion mode (normally-on) devices, in that they are conductive at a gate-source bias of zero due to the polarization-induced charge at the interface of the barrier and channel layers of the device.

When a HEMT device is in an ON-state, a two-dimensional electron gas (2DEG) is formed at the heterojunction of two semiconductor materials with different bandgap energies, where the smaller bandgap material has a higher electron affinity. The 2DEG is an accumulation layer in the undoped (“unintentionally doped”) smaller bandgap material and can contain a very high sheet electron concentration. Additionally, electrons that originate in the wider-bandgap semiconductor material transfer to the 2DEG layer, allowing high electron mobility due to reduced ionized impurity scattering. This combination of high carrier concentration and high carrier mobility can give the HEMT a very large transconductance (which may refer to the relationship between output current and input voltage) and may provide a strong performance advantage over MOSFETs for high-frequency applications.

High electron mobility transistors fabricated in Group III-nitride based material systems also have the potential to generate large amounts of radio frequency (RF) power because of the combination of material characteristics that includes the aforementioned high breakdown fields, wide bandgaps, large conduction band offset, and/or high saturated electron drift velocity. As such, Group III-Nitride based HEMTs may be promising candidates for high power RF applications, as well as for low frequency high power switching applications. However, problems may arise as device integration increases.

### SUMMARY

According to some embodiments, a transistor device includes a semiconductor structure comprising an implanted region adjacent a surface thereof; and a source/drain contact comprising an ohmic contact portion on the implanted region of the semiconductor structure. The implanted region laterally extends beyond the ohmic contact portion by less than about 0.8 microns.

In some embodiments, the implanted region laterally extends less than about 0.2 microns from an edge of the ohmic contact portion. For example, the implanted region may laterally extend beyond the edge of the ohmic contact portion by less than about 0.2 microns, 0.1 microns, or 0.05 microns, or may laterally extend within about 0.2 microns, 0.1 microns, or 0.05 microns of the edge of the ohmic contact portion.

In some embodiments, the implanted region laterally extends beyond an edge of the ohmic contact portion by less than about 0.1 microns. For example, the implanted region may laterally extend beyond the edge of the ohmic contact portion by less than about 0.05 microns.

In some embodiments, an electrical resistance of a lateral extension of the implanted region beyond an edge of the ohmic contact portion is substantially zero.

In some embodiments, a boundary of the implanted region is substantially aligned with an edge of the ohmic contact portion.

In some embodiments, the semiconductor structure comprises a channel layer and a barrier layer thereon, and wherein the ohmic contact portion of the source/drain contact extends into a recess in the barrier layer.

In some embodiments, the source/drain contact further comprises an extension portion on the barrier layer outside the recess and laterally extending beyond a boundary of the implanted region.

In some embodiments, the extension portion laterally extends on the barrier layer beyond the boundary of the implanted region by about 0.2 microns to about 0.4 microns.

In some embodiments, an electrical conduction path between a channel region of the semiconductor structure and the source/drain contact comprises a first resistance between the semiconductor structure and a boundary of the implanted region, and a second resistance between the implanted region and the ohmic contact portion; and the implanted region is substantially free of a third resistance between the boundary of thereof and an edge of the ohmic contact portion.

In some embodiments, a lateral distance between the source/drain contact and an adjacent source/drain contact is about 3 microns or less, and an on-resistance of the transistor device is less than about 1.7 ohm-millimeters.

According to some embodiments, a transistor device includes a semiconductor structure comprising a contact region adjacent a surface thereof; and a source/drain contact comprising an ohmic contact portion on the contact region of the semiconductor structure. An electrical resistance of a lateral extension of the contact region beyond an edge of the ohmic contact portion is substantially zero.

In some embodiments, an electrical conduction path between a channel region of the semiconductor structure and the source/drain contact comprises a first resistance between the semiconductor structure and a boundary of the contact region, and a second resistance between the contact region and the ohmic contact portion. The contact region is substantially free of a third resistance between the boundary thereof and the edge of the ohmic contact portion.

In some embodiments, the boundary of the contact region is substantially aligned with the edge of the ohmic contact portion.

In some embodiments, the semiconductor structure comprises a channel layer and a barrier layer thereon comprising a recess therein, where the edge of the ohmic contact portion is substantially aligned with a sidewall of the recess in the barrier layer.

According to some embodiments, transistor device includes a semiconductor structure comprising implanted regions adjacent a surface thereof; and source and drain contacts on the implanted regions of the semiconductor structure, respectively. A lateral distance between the source and drain contacts is about 3 microns or less, and an on-resistance of the transistor device is less than about 1.7 ohm-millimeters.

In some embodiments, the source and drain contacts respectively comprise ohmic contact portions on the implanted regions, and the implanted regions laterally extend beyond the ohmic contact portions by less than about 0.8 microns.

In some embodiments, the implanted regions laterally extend less than about 0.2 microns from edges of the ohmic contact portions.

In some embodiments, respective boundaries of the implanted regions are substantially aligned with edges of the ohmic contact portions.

According to some embodiments, a method of fabricating a transistor device includes forming an implanted region in a surface of a semiconductor structure; and forming a source/drain contact comprising an ohmic contact portion on the implanted region of the semiconductor structure such that an edge of the ohmic contact portion is self-aligned with a boundary of the implanted region.

In some embodiments, the semiconductor structure comprises a channel layer and a barrier layer thereon, and forming the implanted region comprises forming a first mask that exposes a portion of the barrier layer; performing an implantation process using the first mask to form the implanted region; and performing an etching process using the first mask to form a recess in the portion of the barrier layer exposed thereby.

In some embodiments, the recess is formed before the implanted region.

In some embodiments, the recess is formed after the implanted region.

In some embodiments, an annealing process is performed to activate dopants in the implanted region, and the recess is formed before or after the annealing process.

In some embodiments, the annealing process is performed before or after forming the source/drain contact on the implanted region.

In some embodiments, responsive to performing the annealing process, the boundary of the implanted region laterally extends beyond the edge of ohmic contact portion by less than about 0.2 microns.

In some embodiments, forming the source/drain contact comprises forming a second mask that exposes the implanted region, where an opening of the second mask comprises one or more dimensions that are larger than the recess; and forming the source/drain contact in the opening of the second mask.

In some embodiments, the source/drain contact comprises the ohmic contact portion in the recess, and an extension portion on the barrier layer outside the recess and laterally extending beyond the boundary of the implanted region and within the opening of the second mask.

In some embodiments, the extension portion laterally extends on the barrier layer beyond the boundary of the implanted region by about 0.2 microns to about 0.4 microns.

In some embodiments, an electrical resistance of a lateral extension of the implanted region between the boundary thereof and the edge of the ohmic contact portion is substantially zero.

Other devices, apparatus, and/or methods according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

FIG. 1A is a schematic plan view of a Group III nitride-based transistor die according to embodiments of the present invention.

FIG. 1B is a cross-sectional view taken along line 1B-1B′ of FIG. 1A illustrating transistor devices including contact regions with reduced lateral extension according to embodiments of the present invention.

FIGS. 2A, 2B, and 2C are schematic cross-sectional views illustrating examples of region II, III of FIG. 1B in transistor devices including contact regions with reduced lateral extension in accordance with some embodiments of the present disclosure.

FIGS. 3A, 3B, and 3C are schematic cross-sectional views illustrating examples of region II, III of FIG. 1B in transistor devices including contact regions with reduced lateral extension in accordance with some embodiments of the present disclosure.

FIG. 4A illustrates an electrical conduction path between a conduction channel and a source/drain contact in transistor devices including contact regions with reduced lateral extension in accordance with some embodiments of the present disclosure.

FIG. 4B is a graph illustrating reduction in on-resistance versus drain-to-source distance in transistor devices including contact regions with reduced lateral extension in accordance with some embodiments of the present disclosure.

FIGS. 5A, 5B, 5C, 5D, and 5E are schematic cross-sectional views illustrating methods of fabricating transistor devices including contact regions with reduced lateral extension in accordance with some embodiments of the present disclosure.

FIGS. 6A, 6B, 6C, 6D, and 6E are schematic cross-sectional views illustrating methods of fabricating transistor devices including contact regions with reduced lateral extension in accordance with some embodiments of the present disclosure.

FIGS. 7A, 7B, and 7C illustrate implanted regions and ohmic contacts in a conventional device.

FIGS. 8A, 8B, and 8C are schematic cross-sectional views illustrating example packages including transistor devices including contact regions with reduced lateral extension according to embodiments of the present invention to provide packaged transistor amplifiers.

### DETAILED DESCRIPTION OF EMBODIMENTS

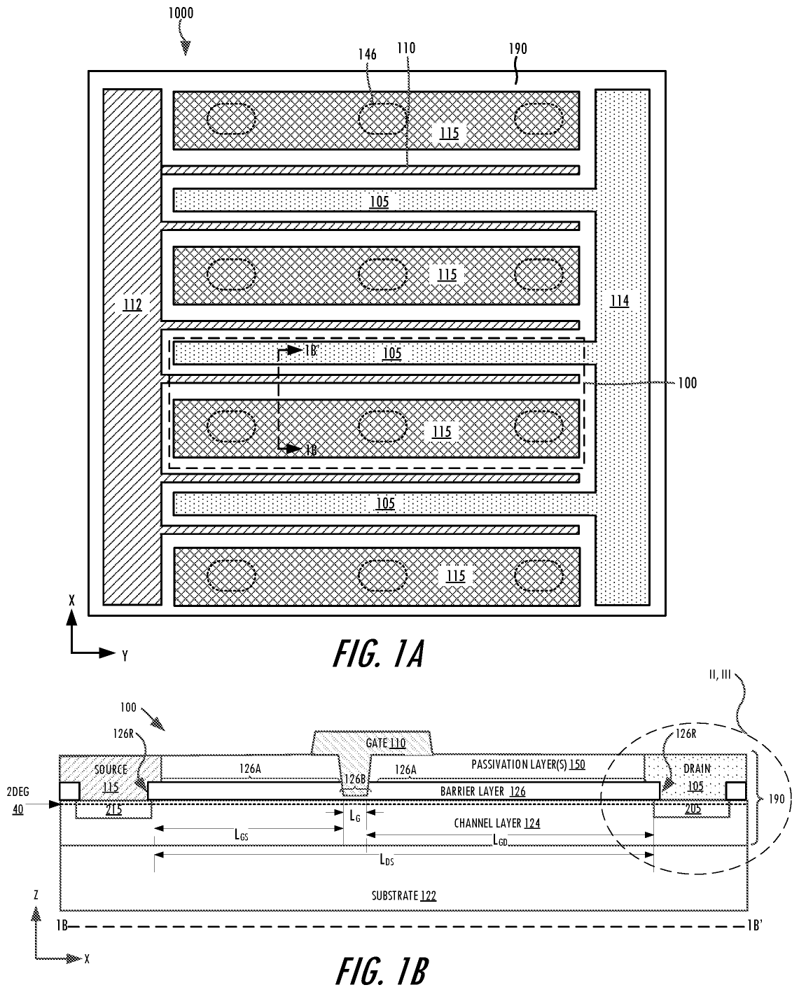

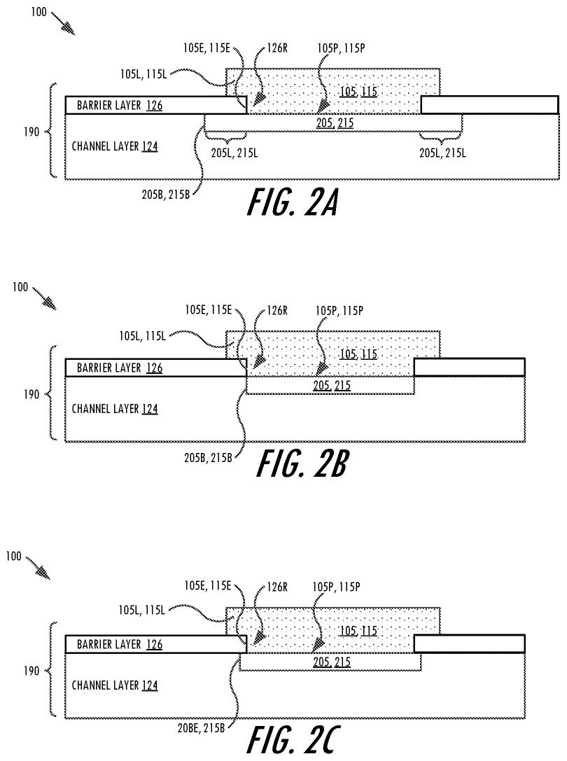

FIG. 1A is a schematic plan view of a Group III nitride-based transistor die according to embodiments of the present invention that illustrates metallization on a surface of the semiconductor structure thereof. As shown in FIG. 1A, a transistor device or die 1000 may include multiple unit cell transistor structures 100 (also referred to herein as a transistor structure or transistor cell) connected in parallel to device terminals or electrodes (e.g., an input terminal, an output terminal, and a ground terminal). For example, each of the gate 110, drain 105, and source 115 contacts may extend in a first direction (e.g., the Y-direction) to define gate, drain, and/or source ‘fingers’, which may be connected by one or more respective buses (e.g., by a gate bus and a drain bus on an upper surface of the semiconductor structure 190.

In FIG. 1A, the gate fingers 110, drain fingers 105 and source fingers 115 may extend in parallel to each other, with the gate fingers 110 extending from the gate bus 112 in a first direction and the drain fingers 105 extending from the drain bus 114 in a direction opposite the first direction. Each gate finger 110 may be positioned between a drain finger 105 and a source finger 115 to define a unit cell 100. The gate fingers 110, drain fingers 105, and source fingers 315 (and connecting buses) may define part of gate-, drain-, and source-connected electrodes of the device, respectively, as defined by a top or frontside metallization structure. Dielectric layers that isolate the various conductive elements of the frontside metallization structure from each other are not shown in FIG. 1A to simplify the drawing. Since the gate fingers 110 are electrically connected to a common gate bus 112, the drain fingers 105 are electrically connected to a common drain bus 114, and the source fingers 115 are electrically connected together (e.g., through respective via openings 146), it can be seen that the unit cell transistors 100 are electrically connected together in parallel.

One of the terminals of the device (e.g., a source terminal connected to the source contact(s) 115) may be configured to be coupled to a reference signal such as, for example, an electrical ground. In some embodiments, a conductive through substrate via connection or structure (e.g., a backside via opening) may extend through the substrate 122 and epitaxial layer(s) 124, 126 to expose a portion of one of the contacts 105, 115, so as to allow for contact pads or terminals on the back side of the substrate (e.g., to couple the source contact 115 to ground). In other embodiments, a ground connection to one of the terminals device (e.g., the source terminal) may be provided outside the active area, e.g., in a peripheral area. In some embodiments, a backmetal layer on the back side of the substrate 122 may provide a backside ground plane, for example, in applications where proximity to ground may be desired.

FIG. 1B is a cross-sectional view taken along line 1B-1B′ of FIG. 1A illustrating a transistor structure according to some embodiments of the present invention. As shown in FIG. 1B, the transistor structure 100 is formed on a substrate 122 such as, for example, a silicon carbide substrate. Hundreds or thousands of unit cell transistor structures 100 may be formed on the semiconductor substrate 122, and may be electrically connected (e.g., in parallel) to provide the HEMT device.

The substrate 122 may be a semi-insulating silicon carbide substrate that may be, for example, the 4H polytype of silicon carbide. Other silicon carbide candidate polytypes may include the 3C, 6H, and 15R polytypes. Although silicon carbide may be used as a substrate material, embodiments of the present disclosure may utilize any suitable substrate, such as sapphire (Al₂O₃), aluminum nitride (AlN), aluminum gallium nitride (AlGaN), gallium nitride (GaN), silicon (Si), GaAs, LGO, zinc oxide (ZnO), LAO, indium phosphide (InP), and the like. The substrate 122 may be a SiC wafer, and the HEMT device may be formed, at least in part, via wafer-level processing. The wafer may then be diced or otherwise singulated to provide a multiple dies, where each die includes a plurality of the unit cell transistor structures 100.

The transistor structure 100 includes a channel layer 124 on the substrate 122, and a barrier layer 126 on the channel layer 124 opposite the substrate 122. Source and drain electrodes (also referred to herein as source and drain contacts) 115 and 105 extend laterally (e.g., along the Y-direction) and are spaced apart from each other (e.g., along the X-direction). The source contact 115 and the drain contact 105 may form ohmic contact to the barrier layer 126 or to the channel layer 124.

One or more insulator layers (for example, one or more passivation layers) 150 are formed on the barrier layer 126, and a gate contact (or simply “gate”) 110 is formed on the barrier layer 126 between the source and drain contacts 115 and 105. The gate 110 may be formed closer to the source contact 115, such that the gate-to-source length Los may be smaller than the gate-to-drain length LGD in some embodiments. Depending on configuration, one or more of the insulator layers 150 may be formed before and/or after formation of the gate 110.

The channel layer 124 may have a bandgap that is less than the bandgap of the barrier layer 126 and the channel layer 124 may also have a larger electron affinity than the barrier layer 126. The channel layer 124 and barrier layer 126 may together define a semiconductor structure 190, with the source contact 115, the drain contact 105, and the gate 110 formed on the semiconductor structure 190. In the illustrated examples, the semiconductor structure 190 may be a semiconductor layer structure including one or more layers formed by epitaxial growth, and thus include one or more epitaxial layers 124, 126. Techniques for epitaxial growth of Group III nitrides have been described in, for example, U.S. Pat. Nos. 5,210,051, 5,393,993, and 5,523,589, the disclosures of which are also incorporated by reference herein in their entireties.

In the illustrated HEMT device 1000, the semiconductor layer structure 190 may be Group-III nitride based, although other material systems can also be used. As noted above, Group III nitrides may refer to semiconductor compounds formed between nitrogen and the elements in the Group III of the periodic table, such as aluminum (Al), gallium (Ga), and/or indium (In), and may form binary (e.g., GaN), ternary (e.g., AlGaN, AlInN), and quaternary (e.g., AlInGaN) compounds. Accordingly, formulas such as AlₓGa₁₋ₓN, where 0≤x≤1, may be used to describe these compounds. One or both of the channel layer 124 and the barrier layer 126 may include sub-layers including doped or undoped (i.e., “unintentionally doped”) layers of Group III-nitride materials, including material compositions which may be stepwise or continuously graded. For example, the channel layer 124 may be a multi-layer structure, such as a superlattice or combinations of GaN, AlGaN or the like. The channel layer 124 may be under compressive strain in some embodiments. The barrier layer 126 may comprise a single layer or may be a multi-layer structure. In particular embodiments of the present disclosure, the barrier layer 126 may be thick enough and may have a high enough aluminum (Al) composition and doping to induce a significant carrier concentration at the interface between the channel layer 124 and the barrier layer 126 through polarization effects when the barrier layer 126 is buried under ohmic contact metal.

While semiconductor structure 190 is shown with reference to one or more epitaxial layers 124, 126 for purposes of illustration, the semiconductor structure 190 may include additional layers/structures/elements such as isolation layer(s), buffer and/or nucleation layer(s) on or between substrate 122 and the one or more epitaxial layers 124, and/or a cap layer on an upper surface of the epitaxial layer 126. For example, an AlN buffer layer may be formed on the upper surface of the substrate 122 to provide an appropriate crystal structure transition between the silicon carbide substrate 122 and the remainder of the layers of the semiconductor structure 190. Additionally, strain balancing transition layer(s) may also and/or alternatively be provided. The optional buffer/nucleation/transition layers, as well as the channel layer 124 and/or the barrier layer 126, may be deposited, for example, by metal-organic chemical vapor deposition (MOCVD), molecular beam epitaxy (MBE), and/or hydride vapor phase epitaxy (HVPE).

The material of the gate 110 may be chosen based on the composition of the semiconductor structure 190, and may, in some embodiments, be a Schottky contact. Some materials capable of making a Schottky contact to a Group III nitride based semiconductor material that may be used as the gate 110 may include, for example, nickel (Ni), platinum (Pt), nickel silicide (NiSiₓ), copper (Cu), palladium (Pd), chromium (Cr), tungsten (W) and/or tungsten silicon nitride (WSiN).

The source contact 115 and/or the drain contact 105 may include a metal (also referred to herein as an ohmic metal) that can form an ohmic contact to the semiconductor material of the structure 190. For example, a conductive metal material may be deposited and annealed (e.g., at a temperature of about 600° C. to 1050° C.) to form the ohmic contacts. Suitable metals may include refractory metals, such as Ti, W, titanium tungsten (TiW), silicon (Si), titanium tungsten nitride (TiWN), tungsten silicide (WSi), rhenium (Re), Niobium (Nb), Ni, gold (Au), aluminum (Al), tantalum (Ta), molybdenum (Mo), NiSiₓ, titanium silicide (TiSi), titanium nitride (TiN), WSiN, Pt and the like. Thus, the source contact 115 and/or the drain contact 105 may contain an ohmic contact portion in direct contact with the semiconductor structure 190 (e.g., direct contact with layer 124 and/or 126) and defining an interface therebetween. In some embodiments, the source contact 115 and/or the drain contact 105 may be formed of a plurality of layers to form an ohmic contact that may be provided as described, for example, in commonly assigned U.S. Pat. Nos. 8,563,372 and 9,214,352, the disclosures of which are hereby incorporated herein in their entirety by reference.

In operation, a 2DEG layer 40 may be formed at a junction between the channel layer 124 and the barrier layer 126 when the HEMT device is biased to be in its conducting or “on” state. The 2DEG layer 40 acts as a highly conductive channel that allows current to flow between the source and drain regions that are beneath the source contact 115 and the drain contact 105, respectively. In particular, the channel layer 124 and the barrier layer 126 of the semiconductor structure 190 may be formed of materials having different bandgaps, such that a heterojunction is defined at an interface between the channel layer 124 and the barrier layer 126. The 2DEG conduction channel 40 can be induced at the heterointerface between the channel layer 124 and the barrier layer 126. The channel layer 124, 2DEG conduction channel 40, and barrier layer 126 can generally form the active region of the HEMT device. It should be noted that while described herein primarily with reference to fabrication and structures of HEMT devices, the elements and concepts of embodiments described herein can be applied to many different types of transistor structures.

In some embodiments, the transistor device 1000 includes a gallium-based semiconductor structure 190 that is formed on the substrate 122 (e.g., a silicon carbide substrate). As used herein, the term “gallium-based” refers to semiconducting compounds that include at least gallium, for example, GaN or GaAs. In some embodiments, the gallium-based semiconductor structure 190 may include, for example, a gallium nitride-based channel layer 124 (e.g., a GaN channel layer) and a gallium nitride based-barrier layer 126 (e.g., an AlGaN barrier layer) that is formed on the gallium nitride-based channel layer 124 opposite the substrate 122. Gallium nitride-based semiconductor structures 190 may include at least gallium and nitrogen, including gallium nitride (GaN) as well as ternary and quaternary compounds such as aluminum gallium nitride (AlGaN) and aluminum indium gallium nitride (AlInGaN).

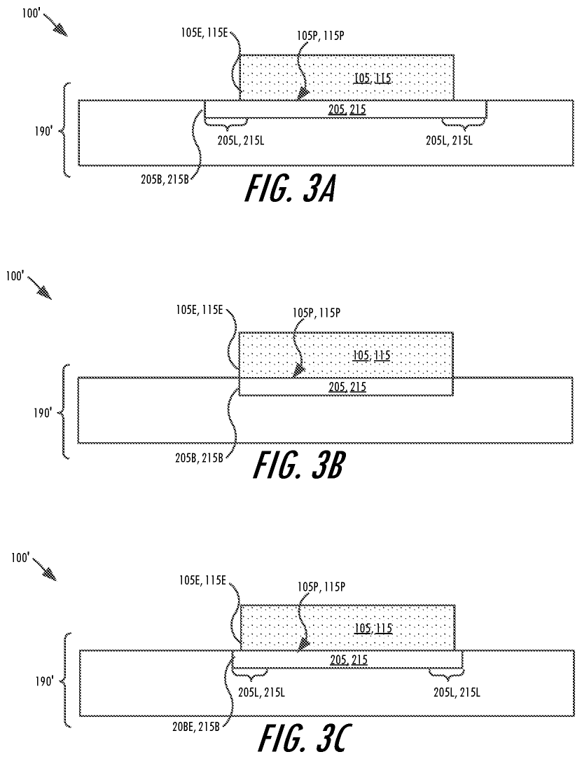

A plurality of enhancement and/or depletion mode transistor structures 100 may be formed on and in the gallium-based semiconductor structure 190. The source and drain contacts 115 and 105 (which may collectively be referred to herein as source/drain contacts) may be formed on the semiconductor structure 190, and the gate may be formed on the barrier layer 126 between the contacts 115 and 105. For example, the source/drain contacts 115 and 105 may be formed as ohmic contacts (e.g., with ohmic contact portions 105P, 115P on implanted regions 205, 215 in the channel layer 124; see FIGS. 2A to 2C) such that an electric current flows between the source and drain contacts 115 and 105 via the 2DEG channel region 40 induced at the heterointerface between the channel layer 124 and barrier layer 126 when the gate 110 is biased at an appropriate level. The implanted regions 215 and 205 may have a lower electrical resistance than that of the semiconductor structure 190 (e.g., the channel layer 124) by about 3 times or more, and thus, may provide a low resistance interface with the ohmic contact portions of the source/drain contacts 115 and 105.

Some conventional ohmic contacts may be formed by performing an implantation process using an implant mask (e.g., a first mask) to form implanted regions in the semiconductor structure (e.g., an AlGaN/GaN heterostructure), annealing the implanted regions, performing an etching process to form recess that exposes a sublayer of the semiconductor structure (e.g., to etch through the AlGaN layer and expose the GaN layer) using an etch mask (e.g., a second mask), and forming the ohmic contacts on the implanted regions using a contact mask (e.g., a third mask). Misalignment of the ohmic contacts with respect to the implanted regions may significantly affect on-resistance and device performance.

To avoid misalignment issues, the first mask used to form the implanted region may be larger than the second mask used to form the recess, and may also be larger than the third mask used to form the ohmic contact metal. The implanted region may thus laterally extend beyond an edge of the ohmic contact, which may contribute to increased contact resistance.

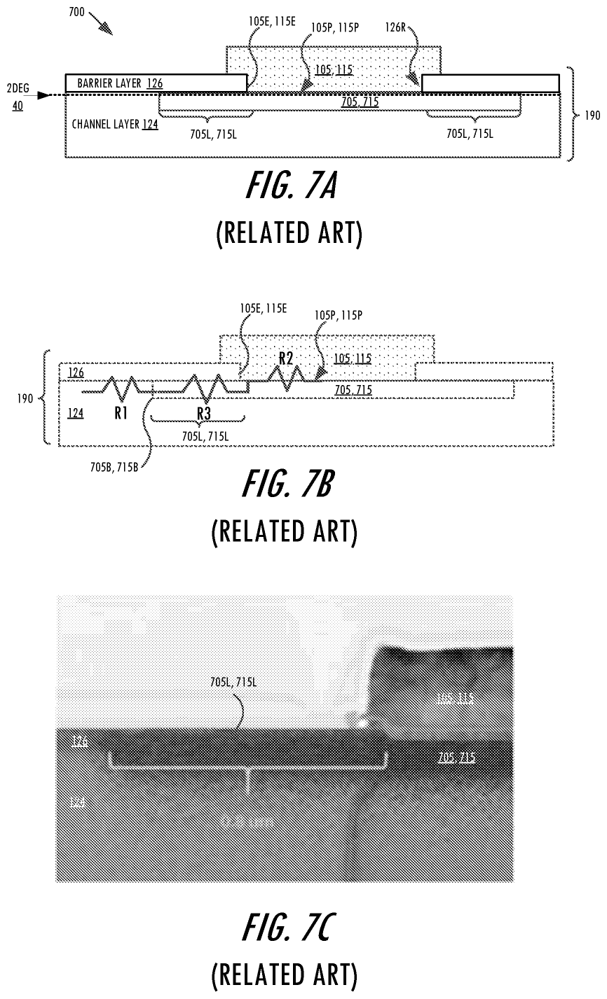

FIGS. 7A, 7B, and 7C illustrate implanted regions 705, 715 in a conventional transistor structure 700. As shown in FIGS. 7A and 7C, the implanted region 705, 715 may laterally extend beyond an edge of the ohmic contact 105, 115 by more than about 0.8 microns (e.g., by about 1 micron) at each side, thereby increasing contact resistance. In the example of FIGS. 7A and 7C, the ohmic contact is formed in a recess 126R in a barrier layer 126 that exposes the implanted region 705, 715 in a GaN structure 190. This forms a 0.8-1 micron gap or lateral extension 705L, 715L between the GaN channel layer 124 and the ohmic metal 105P, 115P in the conduction path (along the 2DEG 40), where such misalignment can affect device performance. For example, the lateral extension 705L, 715L may contribute to up to about 25% of the contact resistance of the device 700.

In particular, as shown in FIG. 7B, the contact resistance between the channel region and the ohmic contact 105, 115 may include several components: (i) a resistance R1 at the interface between the channel layer 124 (or channel region 40) and the boundary 705B, 715B of the implanted region 705, 715; (ii) a resistance R2 between the implanted region 705, 715 and the ohmic contact portion 105P, 115P; and (iii) a resistance R3 of the lateral extension 705L, 715L of the implanted region 705, 715 between the boundary 705B, 715B of the implanted region 705, 715 and the edge 105E, 115E of the ohmic contact portion 105P, 115P. Such resistance contributions may not significantly contribute to an on-resistance of a RF transistor device having relatively large drain-to-source distances (e.g., of about 5 microns or more) and lower operating frequency ranges (e.g., of about 10 GHz or less).

Some embodiments of the present disclosure may arise from realization that, as device sizes are reduced (e.g., with drain-to-source distances L_{DS} of about 3 microns or less) and as device operating frequency ranges increase (e.g., from about 10 GHz to about 30 GHz or more), the lateral extension of the implanted region beyond the ohmic contact region may significantly contribute to the on-resistance of a RF transistor device. For example, an implanted region that laterally extends beyond an edge of an ohmic contact by about 0.8 microns may contribute to about 25% of the on resistance in devices with drain-to-source distances L_{DS} of about 3 microns or less and/or operating frequency ranges of about 30 GHz or more.

Accordingly, embodiments of the present disclosure may include configurations of ohmic contacts (e.g., at the drain and/or source regions) and implanted regions (more generally referred to herein as ohmic contact regions, or contact regions) that can significantly reduce device on-resistance. In particular, some embodiments may reduce or eliminate the resistance R3 of the lateral extension of the implanted regions, that is, such that an electrical conduction path between a channel region of the semiconductor structure and the source/drain contact is substantially free of the resistance R3 between the boundary of thereof and an edge of the ohmic contact portion.

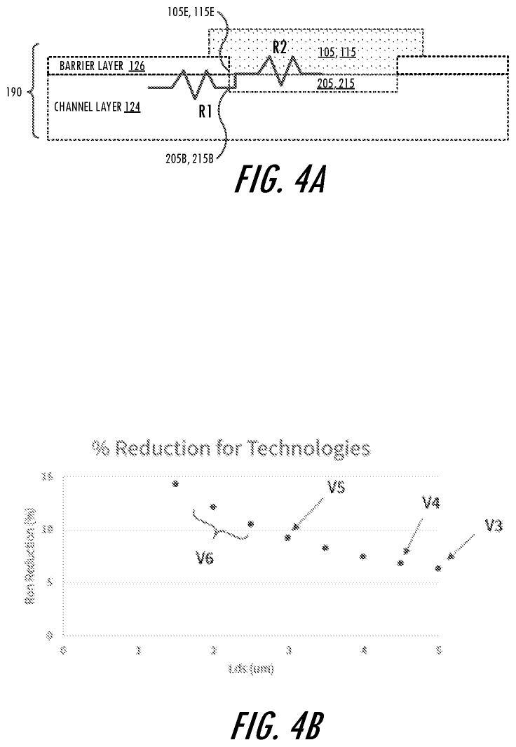

FIGS. 2A, 2B, and 2C are schematic cross-sectional views illustrating an examples of region II, III of FIG. 1B, in a transistor cell 100 having a semiconductor structure 190 including a channel layer and a accordance with some embodiments of the present disclosure. FIGS. 3A, 3B, and 3C are schematic cross-sectional views illustrating examples of region II, III of FIG. 1B, in a transistor cell 100′ having a more general semiconductor structure 190′ in accordance with some embodiments of the present disclosure.

As shown in FIGS. 2A and 3A, a transistor cell 100, 100′ includes a semiconductor structure 190, 190′ including a contact region 205, 215 (e.g., an implanted region) adjacent a surface thereof. A source/drain contact 105, 115 is provided on the semiconductor structure 190, 190′. As noted above, the source/drain contact 105, 115 includes an ohmic contact portion 105P, 115P on the implanted region 205, 215 of the semiconductor structure 190, 190′. In the example of FIGS. 2A to 2C, the semiconductor structure 190 includes a channel layer 124 and a barrier layer 126 thereon, and the ohmic contact portion 105P, 115P of the source/drain contact 105, 115 extends into a recess 126R in the barrier layer 126. In the example of FIGS. 3A to 3C, the ohmic contact portion 105P, 115P of the source/drain contact 105, 115 is provided on a semiconductor structure 190′ that does not include a barrier layer 126 thereon.

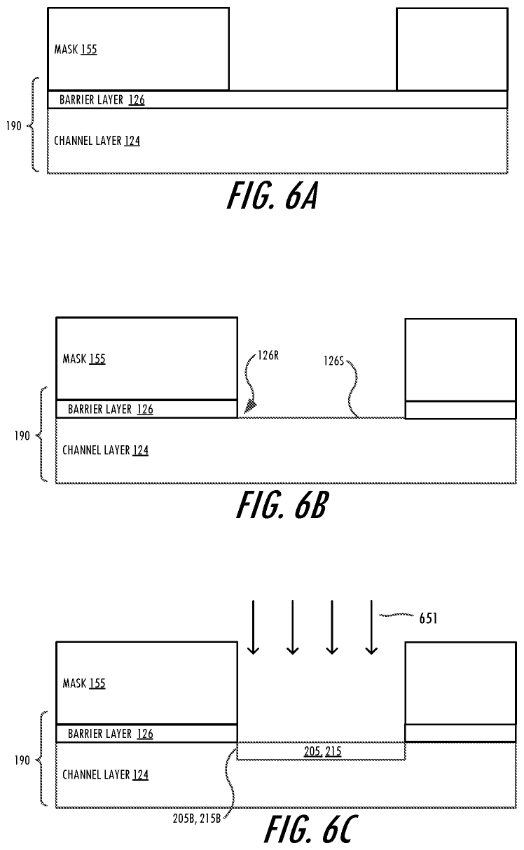

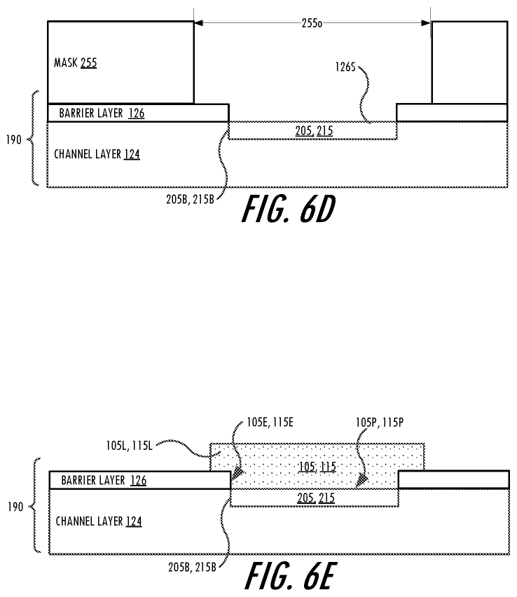

As noted above, the implanted region 205, 215 may have a lower electrical resistance than that of the semiconductor structure 190, 190′. That is, the material of the semiconductor structure 190, 190′ may have a first resistance, and the implanted or other contact region 205, 215 may have a second resistance that is less than the first resistance adjacent the surface of the semiconductor structure 190, 190′. In embodiments of the present disclosure, the amount of lateral extension 205L, 215L of the implanted region 205, 215 beyond the ohmic contact portion 105P, 115P may be limited, thereby reducing contact resistance. For example, as shown in FIGS. 2A and 3A, the implanted region 205, 215 may laterally extend beyond the ohmic contact portion 105P, 115P by less than about 0.8 microns. In some embodiments, as shown in FIGS. 2B and 3B, a boundary 205B, 215B of the implanted region 205, 215 may be substantially aligned (e.g., with a difference of less than about 0.1 micron) with an edge 105E, 115E of the ohmic contact portion 105P, 115P (for example, as formed by a self-aligned process as shown in FIG. 5A to 5E or 6A to 6E). In some embodiments, after forming the implanted regions 205, 215, an anneal process may be performed to activate the implanted dopants, during which the implanted regions 205, 215 may slightly expand (also referred to herein as implant “bloom”), such that the implanted regions 205, 215 may laterally extend beyond the ohmic contact portion 105P, 115P, e.g., by less than about 0.5 microns, 0.2 microns, 0.1 microns, or 0.05 microns at each side. As such, an electrical resistance of the lateral extension 205L, 215L of the implanted region 205, 215 beyond an edge 105E, 115E of the ohmic contact portion 105P, 115P may be substantially zero.

While illustrated in FIGS. 2A, 2C, 3A, and 3C with the implanted region 205, 215 laterally extending beyond the ohmic contact portion 105P, 115P, in some embodiments the implanted region 205, 215 may not laterally extend beyond the ohmic contact portion 105P, 115P. Rather, the boundaries 205B, 215B of the implanted region 205, 215 may be confined within the edges 105E, 115E of the ohmic contact portion 105P, 115P. That is, the ohmic contact portion 105P, 115P may laterally extend beyond the implanted region 205, 215 by less than about 0.2 microns, 0.1 microns, or 0.05 microns in some embodiments.

More generally, the implanted region 205, 215 may laterally extend about ±0.2 microns or less from the edges 105E, 115E of the ohmic contact portion 105P, 115P (e.g., confined within the edges 105E, 115E and along less than an entirety of the ohmic contact portion 105P, 115P, or beyond the edges 105E, 115E and along greater than an entirety of the ohmic contact portion 105P, 115P). For example, the implanted region 205, 215 may laterally extend about ±0.1 microns or about ±0.05 microns within or beyond the edges 105E, 115E.

In the examples of FIGS. 2A to 2C, the source/drain contact 105, 115 further includes an extension portion 105L, 115L on the barrier layer 126 outside the recess 126R. The extension portion 105L, 115L laterally extends beyond a boundary 205B, 215B of the implanted region 205, 215. For example, the extension portion 105L, 115L may laterally extend on the barrier layer 126 beyond the boundary 205B, 215B of the implanted region 205, 215 by about 0.1 or 0.2 microns to about 0.4 or 0.5 microns. The extension portion 105L, 115L may result from the use of a contact mask pattern having an opening therein that is larger than that of the recess 126R in the barrier layer 126, to ensure that the recess 126R is substantially filled by the ohmic contact metal and avoid misalignment of the ohmic contact portion 105P, 115P of the source/drain contact 105, 115 with respect to the implanted region 205, 215.

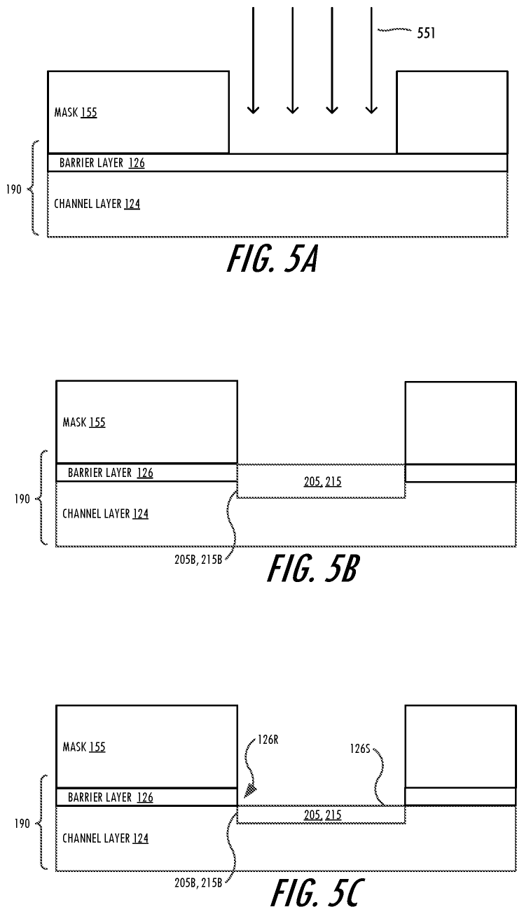

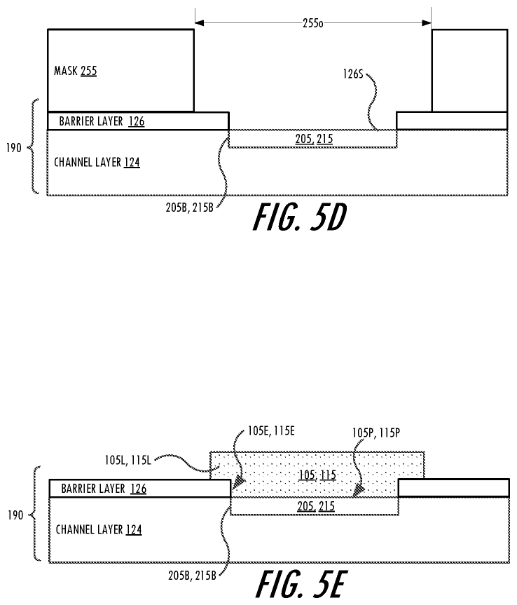

FIG. 4A is a schematic illustration of an electrical conduction path between the conduction channel and a source/drain contact 105, 115 in a transistor structure 100, 100′ including contact regions 205, 215 with reduced lateral extension in accordance with some embodiments of the present disclosure. As shown in FIG. 4A, a transistor structure 100, 100′ includes a semiconductor structure 190, 190′ having a contact region 205, 215 (e.g., an implanted region) adjacent a surface thereof. A source/drain contact 105, 115 including an ohmic contact portion 105P, 115P is provided on the contact region 205, 215 of the semiconductor structure. In the example of FIG. 4A, the semiconductor structure includes a channel layer 124 and a barrier layer 126 thereon comprising a recess 126R therein, with the edge 105E, 115E of the ohmic contact portion 105P, 115P is aligned with a sidewall of the recess 126R in the barrier layer 126, similar to the semiconductor structure 190 of FIGS. 2A to 2C. However, in some embodiments, the semiconductor structure may not include a barrier layer 126, similar to the semiconductor structure 190′ of FIGS. 3A to 3C.

FIG. 4A illustrates that an electrical resistance of a lateral extension of the contact region 205, 215 beyond an edge 105E, 115E of the ohmic contact portion 105P, 115P is substantially zero. In particular, an electrical conduction path between a channel region of the semiconductor structure 190, 190′ and the source/drain contact 105, 115 includes a first resistance R1 between the semiconductor structure 190, 190′ and a boundary 205B, 215B of the contact region 205, 215, and a second resistance R2 between the contact region 205, 215 and the ohmic contact portion 105P, 115P. However, in contrast to the conventional device 700 shown in FIG. 7B, the contact region 205, 215 is substantially free of a third resistance (R3) between the boundary 205B, 215B thereof and the edge 105E, 115E of the ohmic contact portion 105P, 115P. For example, the boundary 205B, 215B of the contact region 205, 215 may be substantially aligned with the edge 105E, 115E of the ohmic contact portion 105P, 115P. As such, a lateral extension (and an electrical resistance associated therewith) of the implanted region 205, 215 between the boundary 205B, 215B thereof and the edge 105E, 115E of the ohmic contact portion 105P, 115P may be reduced or substantially eliminated.

FIG. 4B is a graph illustrating reduction in on-resistance Ron versus drain-to-source distance L_{DS} in transistor structures including contact regions 205, 215 with reduced lateral extension relative to (for example, within less than about 0.8 microns, less than about 0.5 microns, less than about 0.2 microns, less than about 0.1 micron, or less than about 0.05 microns of) edges 105E, 115E of adjacent source/drain contacts 105 and 115, or having boundaries 205B, 215B substantially aligned with edges 105E, 115E of adjacent source/drain contacts 105 and 115 in accordance with some embodiments of the present disclosure. As shown in FIG. 4B, as drain-to-source distance Los between the source contact 115 and the drain contact 105 is reduced, contact regions 205, 215 having reduced lateral extension relative to edges 105E, 115E of the source/drain contacts 105, 115 can significantly reduce on-resistance Ron. In particular, on-resistance Ron may be reduced by more than about 6% in devices with a drain-to-source distance L_{DS} of less than about 5 microns; by more than about 7.5% in devices with a drain-to-source distance L_{DS} of less than about 4 microns; and by more than about 10% in devices with a drain-to-source distance L_{DS} of about 3 microns or less. For example in some embodiments, the on-resistance Ron of the transistor structure 100, 100′ may be less than about 1.7 ohm-millimeters (e.g., about 0.8 to about 1.5 ohm-millimeters, or about 1 to about 1.3 ohm-millimeters) when the lateral distance L_{DS} between the source contact 115 and the drain contact 105 is about 3 microns or less. Accordingly, transistor structures including contact regions 205, 215 with reduced lateral extension 205L, 215L as described herein can reduce on-resistance over some conventional designs, particularly for transistor cells where the drain-to-source distance Los is smaller than 3 microns.

FIGS. 5A to 5E and FIGS. 6A to 6E are schematic cross-sectional views illustrating methods of fabricating transistor structures including contact regions 205, 215 with reduced lateral extension in accordance with some embodiments of the present disclosure. In the illustrated examples, a contact region 205, 215 is formed in a surface of a semiconductor structure 190, 190′ having a channel layer 124 and a barrier layer 126, and a source/drain contact 105, 115 is formed with an ohmic contact portion 105P, 115P thereof on the contact region 205, 215. A same mask is used in implanting the contact region 205, 215 and etching or otherwise exposing the surface of the semiconductor structure 190, 190′ for formation of the source/drain contact 105, 115, such that an edge 105E, 115E of the ohmic contact portion 105P, 115P is self-aligned with a boundary 205B, 215B of the contact region 205, 215.

In particular, FIGS. 5A to 5C illustrate methods in which the implantation process 551 is performed before etching the surface of the semiconductor layer structure. As shown in FIG. 5A, a first mask 155 is formed on a surface of the semiconductor structure 190, 190′ so as to expose a portion of the barrier layer 126, and an implantation process 551 is performed using the first mask 155 as an implantation mask. The implantation process 551 may be performed with an implantation energy sufficient to form the implanted region 205, 215 with a desired depth in the semiconductor structure 190, 190′ (e.g., extending through the barrier layer 126 and into the channel layer 124), as shown in FIG. 5B. In FIG. 5C, an etching process is performed using the first mask 155 as an etch mask to form a recess 126R in the surface 126S of the barrier layer 126 exposed thereby. The recess 126R is thus formed after the implanted region 205, 215.

Alternatively, FIGS. 6A to 6C illustrate methods in which the implantation process 651 is performed after etching the surface of the semiconductor layer structure. As shown in FIG. 6A, a first mask 155 is formed on a surface of the semiconductor structure 190, 190′ so as to expose a portion of the barrier layer 126, and an etching process is performed using the first mask 155 as an etch mask to form a recess 126R in the surface 126S of the barrier layer 126 exposed thereby, as shown in FIG. 6B. In FIG. 6C, an implantation process 651 is performed using the first mask 155 as an implantation mask. The implantation process 651 may be performed with an implantation energy sufficient to form the implanted region 205, 215 with a desired depth in the semiconductor structure 190, 190′. The implantation process 651 may be performed with a comparatively lower implantation energy than the implantation process 551 of FIG. 5A, as the barrier layer 126 has been previously etched in FIG. 6B. That is, the recess 126R is formed before the implanted region 205, 215.

As shown in FIGS. 5D and 6D, the first mask 155 is removed and a second mask 255 is formed to expose the implanted region 205, 215. The second mask 255 includes an opening 2550 having one or more dimensions that are larger than the recess 126R, or more generally, larger than an opening in the first mask 155 used to form the implanted region. The source/drain contact 105, 115 is formed in the opening 2550 of the second mask 255, as shown in FIGS. 5E and 6E. Due to the comparatively larger dimension(s) of the opening 2550 in the second mask 255, the source/drain contact 105, 115 includes the ohmic contact portion 105P, 115P in the recess 126R, and an extension portion 105L, 115L on the barrier layer 126 outside the recess 126R and laterally extending beyond the boundary 205B, 215B of the implanted region 205, 215, within the opening 2550 of the second mask 255. For example, the extension portion 105L, 115L may laterally extend on the barrier layer 126 beyond the boundary 205B, 215B of the implanted region 205, 215 by about 0.1 or 0.2 microns to about 0.4 or 0.5 microns on each side of the recess 126R. The comparatively larger dimension(s) of the opening 2550 in the second mask 255 may thus ensure that the recess 126R is substantially filled by the ohmic contact metal and avoid misalignment of the ohmic contact portion 105P, 115P of the source/drain contact 105, 115 with respect to the implanted region 205, 215. That is, the extension portion 105L, 115L of the source/drain contact 105, 115 may be sufficient to allow for alignment tolerances. Also, as a same mask 155 is used to form the implanted region 205, 215 and to form the recess 126R in the semiconductor structure 190, 190′, a respective edge 105E, 115E of the ohmic contact portion 105P, 115P is self-aligned with a respective boundary 205B, 215B of the implanted region 205, 215.

In any of the methods shown in 5A to 5E and FIGS. 6A to 6E, an annealing process (also referred to as an activation anneal) may be performed to activate dopants in the implanted region 205, 215. The annealing process may be performed at a temperature of about 800° C. to about 1300° C., and may be implemented at any time after forming the implanted region 205, 215. For example, in some embodiments, the annealing process may be performed before or after forming the recess 126R. Likewise, the annealing process may be performed before or after forming the source/drain contact 105, 115. The dopants in the implanted region 205, 215 may expand or “bloom” (e.g., in one or more lateral directions along the surface of the semiconductor structure 190, 190′) during the activation anneal. As such, in some embodiments, the boundary 205B, 215B of the implanted region 205, 215 may be within or substantially aligned with the edge 105E, 115E of the ohmic contact portion 105P, 115P prior to the anneal process, but the boundary 205B, 215B of the implanted region 205, 215 may laterally extend beyond the edge 105E, 115E of ohmic contact portion 105P, 115P (e.g., by less than about 0.5 microns at a respective side, for example, by about 0.2 or 0.1 or 0.05 micron) responsive to performing the annealing process.

Accordingly, in transistor devices and methods according to some embodiments of the present invention, an electrical resistance R3 of a lateral extension of the implanted region between the boundary thereof and the edge of the ohmic contact portion may be reduced or substantially eliminated, which may significantly reduce on-resistance of a transistor device. Reduced device on-resistance may help improve performance of high frequency devices that require higher power and efficiency requirements, particularly as transistor devices (such as GaN-based HEMT devices) become smaller and more highly integrated, as the contact resistance can be a significant component of the total on-resistance of the device. Some embodiments include methods to self-align the edge of the ohmic contact portion with the implanted contact region, e.g., by using a same mask pattern to form the recess in the barrier layer self-aligned with the contact region. This can improve performance by reducing a parasitic resistance as devices are made smaller, e.g., for next generation node technologies.

While embodiments of the present invention have been described herein primarily with reference to particular HEMT devices and structures, the present invention should not be construed as limited to such structures, and may be applied to formation of many different lateral transistor structures, such as LDMOS transistors, pHEMTs (including GaAs/AlGaAs pHEMTs) and/or GaN MESFETs, or more generally, any planar transistor structure with ohmic contacts to an implanted or other contact region. Also, additional layers may be included in transistor structures while still benefiting from the teachings of the present invention. Such additional layers may include GaN cap layers, as described for example U.S. Pat. No. 6,548,333 to Smith. In some embodiments, insulating layers such as SiNx, or relatively high quality AlN may be deposited for making a MISHEMT and/or passivating the surface. The additional layers may also include a compositionally graded transition layer or layers. In addition, the barrier layer 126 and/or channel layer 124 described above may include multiple layers. Thus, embodiments of the present invention should not be construed as limiting these layers to a single layer but may include, for example, barrier layers having combinations of GaN, AlGaN and/or AlN layers.

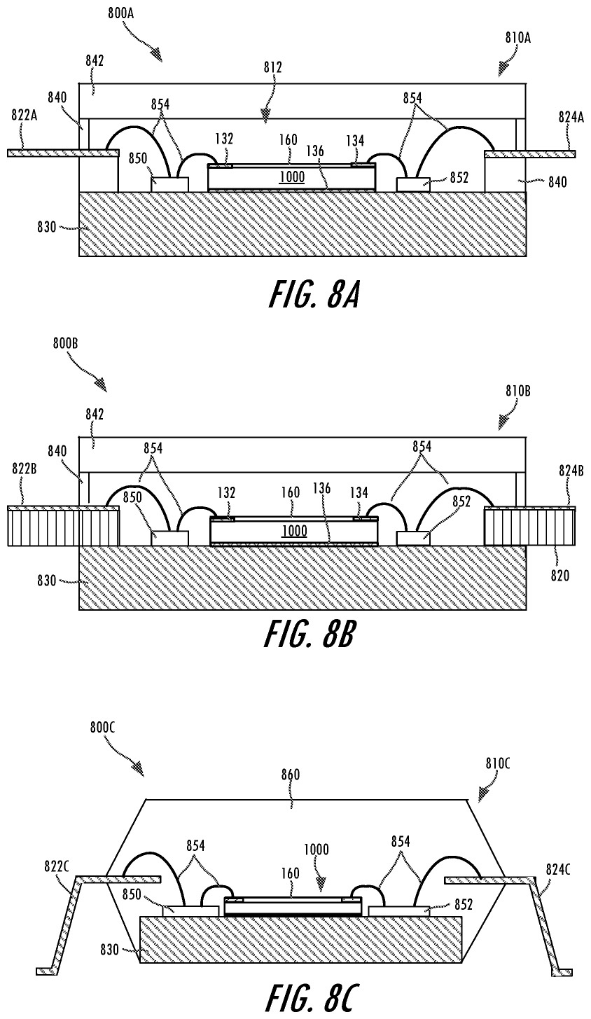

FIGS. 8A, 8B, and 8C are schematic cross-sectional views illustrating several example ways that that the RF transistor amplifier dies according to embodiments of the present invention may be packaged to provide packaged RF transistor amplifiers 800A, 800B, 800C. FIGS. 8A-8C show packaging of the transistor device 1000, which may include any of the transistor structures described herein.

FIG. 8A is a schematic side view of a packaged Group III nitride-based RF transistor amplifier 800A. As shown in FIG. 8A, packaged RF transistor amplifier 800A includes the RF transistor amplifier die 1000 packaged in an open cavity package structure 810A. The package structure 810A includes metal gate leads 822A, metal drain leads 824A, a metal submount 830, sidewalls 840 and a lid 842.

The submount 830 may include materials configured to assist with the thermal management of the package 800A. For example, the submount 830 may include copper and/or molybdenum. In some embodiments, the submount 830 may be composed of multiple layers and/or contain vias/interconnects. In an example embodiment, the submount 830 may be a multilayer copper/molybdenum/copper metal flange that comprises a core molybdenum layer with copper cladding layers on either major surface thereof. In some embodiments, the submount 830 may include a metal heat sink that is part of a lead frame or metal slug. The sidewalls 840 and/or lid 842 may be formed of or include an insulating material in some embodiments. For example, the sidewalls 840 and/or lid 842 may be formed of or include ceramic materials. In some embodiments, the sidewalls 840 and/or lid 842 may be formed of, for example, Al₂O₃. The lid 842 may be glued to the sidewalls 840 using an epoxy glue. The sidewalls 840 may be attached to the submount 830 via, for example, brazing. The gate lead 822A and the drain lead 824A may be configured to extend through the sidewalls 842, though embodiments of the present invention are not limited thereto.

The RF transistor amplifier die 1000 is mounted on the upper surface of the metal submount 830 in an air-filled cavity 812 defined by the metal submount 830, the ceramic sidewalls 840 and the ceramic lid 842. Gate and drain terminals 132, 134 of RF transistor amplifier die 1000 are on the top side of the semiconductor structure 190, while the source terminal 136 is on the bottom side of the semiconductor structure 190. The source terminal 136 may be mounted on the metal submount 830 using, for example, a conductive die attach material (not shown). The metal submount 830 may provide the electrical connection to the source terminal 136 and may also serve as a heat dissipation structure that dissipates heat that is generated in the RF transistor amplifier die 1000.

Input matching circuits 850 and/or output matching circuits 852 may also be mounted within the package 800A. The matching circuits 850, 252 may include impedance matching and/or harmonic termination circuits. The impedance matching circuits may be used to match the impedance of the fundamental component of RF signals that are input to or output from the RF transistor amplifier to the impedance at the input or output of the RF transistor amplifier die 1000, respectively. The harmonic termination circuits may be used to ground harmonics of the fundamental RF signal that may be present at the input or output of the RF transistor amplifier die 1000. More than one input matching circuit 850 and/or output matching circuit 852 may be provided. As schematically shown in FIG. 8A, the input and output matching circuits 850, 852 may be mounted on the metal submount 830. The gate lead 822A may be connected to the input matching circuit 850 by one or more bond wires 854, and the input matching circuit 850 may be connected to the gate terminal 132 of RF transistor amplifier die 1000 by one or more additional bond wires 854. Similarly, the drain lead 824A may be connected to the output matching circuit 852 by one or more bond wires 854, and the output matching circuit 852 may be connected to the drain terminal 134 of RF transistor amplifier die 1000 by one or more additional bond wires 854. The bond wires 854, which are inductive elements, may form part of the input and/or output matching circuits.

FIG. 8B is a schematic side view of a packaged Group III nitride-based RF transistor amplifier 800B that includes the transistor device 1000 packaged in a printed circuit board based package structure 810B. The packaged RF transistor amplifier 800B is similar to the packaged RF transistor amplifier 800A of FIG. 8A, except that the gate and drain leads 822A, 824A of package structure 810A are replaced with printed circuit board based leads 822B, 824B in package structure 810B.

The package structure 810B includes a submount 830, ceramic sidewalls 840, a ceramic lid 842, each of which may be substantially identical to the like numbered elements of package structure 810A discussed above. The package structure 810B further includes a printed circuit board 820. Conductive traces on the printed circuit board 820 form a metal gate lead 822B and a metal drain lead 824B. The printed circuit board 820 may be attached to the submount 830 via, for example, a conductive glue. The printed circuit board 820 includes a central opening and the RF transistor amplifier die 1000 is mounted within this opening on the submount 830. Other components of RF transistor amplifier 800B may be the same as the like-numbered components of RF transistor amplifier 800A, and hence further description thereof will be omitted.

FIG. 8C is a schematic side view of another packaged Group III nitride-based RF transistor amplifier 800C. RF transistor amplifier 800C differs from RF transistor amplifier 800A in that it includes a different package structure 810C. The package structure 810C includes a metal submount 830 (which may be similar or identical to the submount 830 of package structure 810A), as well as metal gate and drain leads 822C, 824C. RF transistor amplifier 800C also includes a plastic overmold 860 that at least partially surrounds the RF transistor amplifier die 1000, the leads 822C, 824C, and the metal submount 830. Other components of RF transistor amplifier 800C may be the same as the like-numbered components of RF transistor amplifier 800A and hence further description thereof will be omitted.

The present invention is described with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entirety.

In the drawings and specification, there have been disclosed typical embodiments of the invention, and, although specific terms have been employed, they have been used in a generic and descriptive sense only and not for purposes of limitation.

That which is claimed:

1. A transistor device, comprising:
a semiconductor structure comprising an implanted region adjacent a surface thereof; and
a source/drain contact comprising an ohmic contact portion on the implanted region of the semiconductor structure,
wherein the implanted region laterally extends beyond the ohmic contact portion by less than about 0.8 microns.

2. The transistor device of claim 1, wherein the implanted region laterally extends less than about 0.2 microns from an edge of the ohmic contact portion.

3. The transistor device of claim 1, wherein the implanted region laterally extends beyond an edge of the ohmic contact portion by less than about 0.1 microns.

4. The transistor device of claim 1, wherein the implanted region laterally extends beyond an edge of the ohmic contact portion by less than about 0.05 microns.

5. The transistor device of claim 1, wherein an electrical resistance of a lateral extension of the implanted region beyond an edge of the ohmic contact portion is substantially zero.

6. The transistor device of claim 1, wherein a boundary of the implanted region is substantially aligned with an edge of the ohmic contact portion.

7. The transistor device of claim 1, wherein the semiconductor structure comprises a channel layer and a barrier layer thereon, and wherein the ohmic contact portion of the source/drain contact extends into a recess in the barrier layer.

8. The transistor device of claim 7, wherein the source/drain contact further comprises an extension portion on the barrier layer outside the recess and laterally extending beyond a boundary of the implanted region.

9. The transistor device of claim 8, wherein the extension portion laterally extends on the barrier layer beyond the boundary of the implanted region by about 0.2 microns to about 0.4 microns.

10. The transistor device of claim 1, wherein:
an electrical conduction path between a channel region of the semiconductor structure and the source/drain contact comprises a first resistance between the semiconductor structure and a boundary of the implanted region, and a second resistance between the implanted region and the ohmic contact portion; and
the implanted region is substantially free of a third resistance between the boundary of thereof and an edge of the ohmic contact portion.

11. The transistor device of claim 1, wherein a lateral distance between the source/drain contact and an adjacent source/drain contact is about 3 microns or less, and an on-resistance of the transistor device is less than about 1.7 ohm-millimeters.

12. A transistor device, comprising:
a semiconductor structure comprising a contact region adjacent a surface thereof; and
a source/drain contact comprising an ohmic contact portion on the contact region of the semiconductor structure,
wherein an electrical resistance of a lateral extension of the contact region beyond an edge of the ohmic contact portion is substantially zero.

13. The transistor device of claim 12, wherein:
an electrical conduction path between a channel region of the semiconductor structure and the source/drain contact comprises a first resistance between the semiconductor structure and a boundary of the contact region, and a second resistance between the contact region and the ohmic contact portion; and
the contact region is substantially free of a third resistance between the boundary thereof and the edge of the ohmic contact portion.

14. The transistor device of claim 13, wherein the boundary of the contact region is substantially aligned with the edge of the ohmic contact portion.

15. The transistor device of claim 14, wherein the semiconductor structure comprises a channel layer and a barrier layer thereon comprising a recess therein, wherein the edge of the ohmic contact portion is substantially aligned with a sidewall of the recess in the barrier layer.

16. A transistor device, comprising:
a semiconductor structure comprising implanted regions adjacent a surface thereof; and
source and drain contacts on the implanted regions of the semiconductor structure, respectively,
wherein a lateral distance between the source and drain contacts is about 3 microns or less, and an on-resistance of the transistor device is less than about 1.7 ohm-millimeters.

17. The transistor device of claim 16, wherein the source and drain contacts respectively comprise ohmic contact portions on the implanted regions, and wherein the implanted regions laterally extend beyond the ohmic contact portions by less than about 0.8 microns.

18. The transistor device of claim 17, wherein the implanted regions laterally extend less than about 0.2 microns from edges of the ohmic contact portions.

19. The transistor device of claim 17, wherein respective boundaries of the implanted regions are substantially aligned with edges of the ohmic contact portions.

20. A method of fabricating a transistor device, the method comprising:
forming an implanted region in a surface of a semiconductor structure; and
forming a source/drain contact comprising an ohmic contact portion on the implanted region of the semiconductor structure such that an edge of the ohmic contact portion is self-aligned with a boundary of the implanted region.

21. The method of claim 20, wherein the semiconductor structure comprises a channel layer and a barrier layer thereon, and wherein forming the implanted region comprises:
forming a first mask that exposes a portion of the barrier layer;
performing an implantation process using the first mask to form the implanted region; and
performing an etching process using the first mask to form a recess in the portion of the barrier layer exposed thereby.

22. The method of claim 21, wherein the recess is formed before the implanted region.

23. The method of claim 21, wherein the recess is formed after the implanted region.

24. The method of claim 21, further comprising:
performing an annealing process to activate dopants in the implanted region,
wherein the recess is formed before or after the annealing process.

25. The method of claim 24, wherein the annealing process is performed before or after forming the source/drain contact on the implanted region.

26. The method of claim 24, wherein, responsive to performing the annealing process, the boundary of the implanted region laterally extends beyond the edge of ohmic contact portion by less than about 0.2 microns.

27. The method of claim 21, wherein forming the source/drain contact comprises:
forming a second mask that exposes the implanted region, wherein an opening of the second mask comprises one or more dimensions that are larger than the recess; and
forming the source/drain contact in the opening of the second mask.

28. The method of claim 27, wherein the source/drain contact comprises the ohmic contact portion in the recess, and an extension portion on the barrier layer outside the recess and laterally extending beyond the boundary of the implanted region and within the opening of the second mask.

29. The method of claim 28, wherein the extension portion laterally extends on the barrier layer beyond the boundary of the implanted region by about 0.2 microns to about 0.4 microns.

30. The method of claim 20, wherein an electrical resistance of a lateral extension of the implanted region between the boundary thereof and the edge of the ohmic contact portion is substantially zero.
